(19) United States
(12) Patent Application Publication
(10) Pub. No.: US 2024/0112851 A1
(43) Pub. Date: Apr. 4, 2024

(54) PLANAR TRANSFORMER

(71) Applicant: Delta Electronics, Inc., Taoyuan City (TW)

(72) Inventors: Caili Gu, Taoyuan City (TW); Xiaoxia Yuan, Taoyuan City (TW); Chun-Ching Yen, Taoyuan City (TW); Yue Tsao, Taoyuan City (TW); Huai-Pei Tung, Taoyuan City (TW); Shaodong Zhang, Taoyuan City (TW); Zhi-Liang Zhang, Taoyuan City (TW)

(21) Appl. No.: 18/097,885

(22) Filed: Jan. 17, 2023

(30) Foreign Application Priority Data
Sep. 30, 2022 (CN) 202211209817.0

(51) Int. Cl. H01F 27/28; H01F 27/24; H01F 27/29; H05K 1/18

(52) U.S. Cl. CPC H01F 27/2847; H01F 27/24; H01F 27/29; H05K 1/182

(57) ABSTRACT

A planar transformer includes a magnetic core assembly, at least one printed circuit board and at least one winding module. The magnetic core assembly includes a first magnetic core and a second magnetic core. The at least one printed circuit board is disposed between the first magnetic core and the second magnetic core. The printed circuit board includes a first winding. The at least one winding module is disposed between the first magnetic core and the second magnetic core. The winding module includes a second winding and a plastic molding layer. At least a portion of the second winding is covered by the plastic molding layer. The at least one printed circuit board and the at least one winding module are individual components.

### CROSS-REFERENCE TO RELATED APPLICATION

This application claims priority to China Patent Application No. 202211209817.0, filed on Sep. 30, 2022, the entire contents of which are incorporated herein by reference for all purposes.

### FIELD OF THE INVENTION

The present disclosure relates to a transformer, and more particularly to a planar transformer.

### BACKGROUND OF THE INVENTION

Nowadays, planar transformers are widely used in electronic devices. When compared with the general transformers, the size of the magnetic core of the planar transformer is greatly reduced, especially its height is greatly reduced. Due to this advantage, the planar transformer is suitably used in the circumstance with limited space. For example, planar transformers are suitably used as magnetic elements of power devices such as chargers.

Conventionally, the planar transformer is a combination of a single circuit board and a magnetic core. The single circuit board has a multi-layered structure comprising a plurality of layers. Generally, all windings of the conventional planar transformer are formed on the single circuit board. For example, the single circuit board includes more than six layers. As the number of layers on the circuit board increases, the fabricating process of the circuit board becomes more complicated, and the production cycle of the conventional planar transformer is longer. Moreover, as the number of layers on the circuit board increases, the manufacturing technique becomes higher, and the fault tolerance rate is lower. Consequently, the fabricating cost of the planar transformer increases.

Moreover, in case that the interlayer capacitance and/or the turn number of the windings in the circuit board of the planar transformer needs to be changed, the design of the circuit board has to be adjusted and re-design of the circuit board is time-consuming. In other words, it is necessary to use a new circuit board. However, since the production cycle of the multi-layered circuit board in the conventional planar transformer is long, it takes a long time to acquire the new circuit board. In other words, the adjusting flexibility of the conventional planar transformer is very low.

Therefore, there is a need of providing an improved planar transformer in order to overcome the drawbacks of the conventional technologies.

### SUMMARY OF THE INVENTION

The present disclosure provides a planar transformer includes at least one printed circuit board and at least one winding module. The at least one printed circuit board and the at least one winding module are individual components. The printed circuit board includes a first winding. The winding module includes a second winding. Due to the special structural design, the production cycle of the planar transformer is shortened, the fault tolerance rate is increased, the fabricating cost is reduced, and the adjusting flexibility is enhanced.

In accordance with an aspect of present disclosure, a planar transformer is provided. The planar transformer includes a magnetic core assembly, at least one printed circuit board and at least one winding module. The magnetic core assembly includes a first magnetic core and a second magnetic core. The at least one printed circuit board is disposed between the first magnetic core and the second magnetic core. The printed circuit board includes a first winding. The at least one winding module is disposed between the first magnetic core and the second magnetic core. The winding module includes a second winding and a plastic molding layer. At least a portion of the second winding is covered by the plastic molding layer. The at least one printed circuit board and the at least one winding module are individual components.

The above contents of the present disclosure will become more readily apparent to those ordinarily skilled in the art after reviewing the following detailed description and accompanying drawings, in which:

### BRIEF DESCRIPTION OF THE DRAWINGS

FIG. 1 is a schematic perspective view illustrating an assembled structure of a planar transformer according to a first embodiment of the present disclosure;

FIG. 2 is a schematic exploded view illustrating the planar transformer as shown in FIG. 1;

FIG. 3 is a schematic perspective view illustrating a second winding of the winding module of the planar transformer as shown in FIG. 1;

FIG. 4 schematically illustrates the wiring structure of a printed circuit board of the planar transformer as shown in FIG. 1;

FIG. 5 is a schematic perspective view illustrating a variant example of the second winding of the planar transformer according to the first embodiment of the present disclosure;

FIG. 6 is a schematic perspective view illustrating an assembled structure of a planar transformer according to a second embodiment of the present disclosure;

FIG. 7 is a schematic exploded view illustrating the planar transformer as shown in FIG. 6; and

FIG. 8 is a schematic exploded view illustrating a planar transformer according to a third embodiment of the present disclosure.

### DETAILED DESCRIPTION OF THE PREFERRED EMBODIMENT

The present disclosure will now be described more specifically with reference to the following embodiments. It is to be noted that the following descriptions of preferred embodiments of this disclosure are presented herein for purpose of illustration and description only. It is not intended to be exhaustive or to be limited to the precise form disclosed.

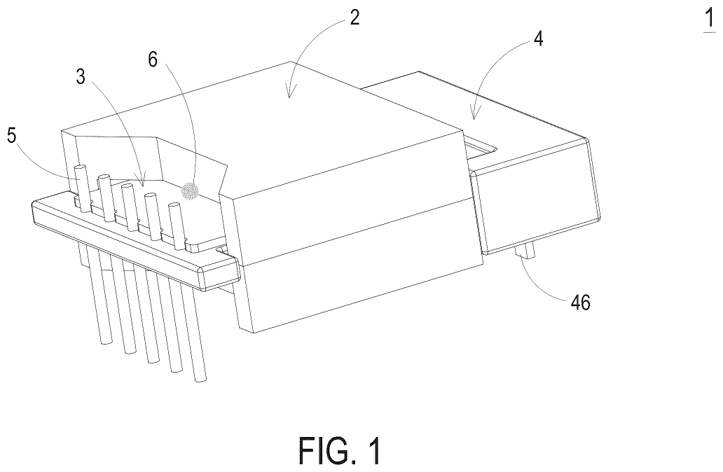

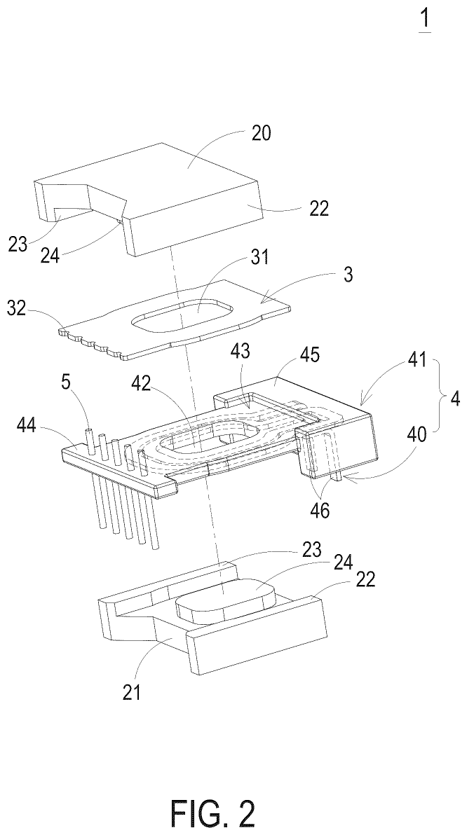

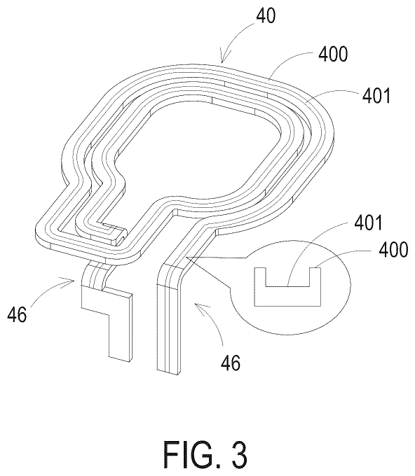

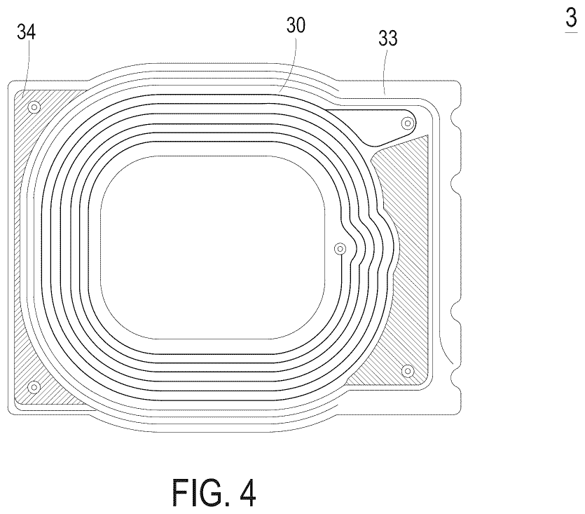

Please refer to FIGS. 1, 2, 3 and 4. FIG. 1 is a schematic perspective view illustrating an assembled structure of a planar transformer according to a first embodiment of the present disclosure. FIG. 2 is a schematic exploded view illustrating the planar transformer as shown in FIG. 1. FIG. 3 is a schematic perspective view illustrating a second winding of the winding module of the planar transformer as shown in FIG. 1. FIG. 4 schematically illustrates the wiring structure of a printed circuit board of the planar transformer as shown in FIG. 1.

The planar transformer 1 of this embodiment is suitably used in thin, small-sized and high-frequency electronic device. In addition, the planar transformer 1 can be automatically assembled and tested. The planar transformer 1 includes a magnetic core assembly 2, at least one printed circuit board 3 and at least one winding module 4.

The magnetic core assembly 2 includes a first magnetic core 20 and a second magnetic core 21. The first magnetic core 20 and the second magnetic core 21 are located at two opposite sides of the planar transformer 1.

The number of the printed circuit board 3 can be one or more. As shown in the FIG. 2, the planar transformer 1 of this embodiment includes one printed circuit board 3. The printed circuit board 3 is disposed between the first magnetic core 20 and the second magnetic core 21. As shown in FIG. 4, the printed circuit board 3 includes a first winding 30. The first winding 30 is formed in the printed circuit board 3. In addition, the first winding 30 is implemented with the traces or conductors in the printed circuit board 3.

The number of the winding module 4 can be one or more. As shown in FIG. 2, the planar transformer 1 of this embodiment includes one winding module 4. The winding module 4 is disposed between the first magnetic core 20 and the second magnetic core 21. In this embodiment, the winding module 4 is disposed between the printed circuit board 3 and the second magnetic core 21. Moreover, the winding module 4 includes a second winding 40 and a plastic molding layer 41. Preferably but not exclusively, the second winding 40 is formed by a conductive sheet (e.g., a copper sheet) subjected to a stamping process. The plastic molding layer 41 is formed on the second winding 40 through a plastic injection molding process, wherein at least a portion of the second winding 40 is covered by the plastic molding layer 41. Due to the arrangement of the plastic molding layer 41, the planar transformer 1 can meet the requirements of the safety regulations.

In this embodiment, the printed circuit board 3 and the winding module 4 are individual components. That is, the printed circuit board 3 and the winding module 4 are not integrally formed as a one-piece structure.

As mentioned above, the planar transformer 1 of this embodiment includes the printed circuit board 3 and the winding module 4, and the printed circuit board 3 and the winding module 4 are individual components. The printed circuit board 3 includes the first winding 30, and the winding module 4 includes the second winding 40. In other words, the windings of the planar transformer 1 are separately formed as the first winding 30 and the second winding 40, and respectively installed on the two individual components. Since the second winding 40 is installed on the winding module 4, the number of winding layers in the printed circuit board 3 of the present disclosure is reduced. That is, the number of winding layers in the printed circuit board 3 of the present disclosure is smaller than the number of layers in a single circuit board of the conventional planar transformer. Under this circumstance, the production cycle of the planar transformer 1 is shortened. Moreover, since manufacturing technique of the printed circuit board 3 becomes lower, the fault tolerance rate is higher, and the fabricating cost of the planar transformer decreases. Moreover, the adjusting flexibility of the planar transformer 1 is enhanced.

In an embodiment, one of the first winding 30 and the second winding 40 is used as a primary winding of the planar transformer 1, and the other of the first winding 30 and the second winding 40 is used as a secondary winding of the planar transformer 1. The thickness of the second winding 40 is in the range between 0.01 mm and 1.5 mm. The second winding 40 is wound for more than two turns. Moreover, the safety protection distance between the first winding 30 and the second winding 40 is equal to 0.4 mm. The safety protection distance can be achieved according to the thickness of the plastic molding layer 41 or the thickness of the printed circuit board 3. In addition, the thickness of the plastic molding layer 41 is in the range between 0.4 mm and 0.8 mm.

In an embodiment, the magnetic core assembly 2 further includes a first lateral leg 22, a second lateral leg 23 and a middle leg 24. The first lateral leg 22 and the second lateral leg 23 are respectively located at two opposite sides of the magnetic core assembly 2. The middle leg 24 is disposed between the first lateral leg 22 and the second lateral leg 23. Moreover, the first lateral leg 22, the second lateral leg 23 and the middle leg 24 are disposed between the first magnetic core 20 and the second magnetic core 21. As shown in FIG. 2, each of the first lateral leg 22, the second lateral leg 23 and the middle leg 24 includes two sub-legs. The first sub-leg of the first lateral leg 22, the first sub-leg of the second lateral leg 23 and the first sub-leg of the middle leg 24 are connected with the first magnetic core 20. The second sub-leg of the first lateral leg 22, the second sub-leg of the second lateral leg 23 and the second sub-leg of the middle leg 24 are connected with the second magnetic core 21.

In some other embodiments, each of the first lateral leg 22, the second lateral leg 23 and the middle leg 24 is a single magnetic leg, and the first lateral leg 22, the second lateral leg 23 and the middle leg 24 are connected with the first magnetic core 20 or the second magnetic core 21.

In an embodiment, the printed circuit board 3 includes a first opening 31, and the winding module 4 includes a second opening 42. The first opening 31 runs through the printed circuit board 3. The second opening 42 runs through the winding module 4. The first opening 31 and the second opening 42 are aligned with the middle leg 24 of the magnetic core assembly 2. When the first magnetic core 20 and the second magnetic core 21 of the magnetic core assembly 2 are respectively fixed on the printed circuit board 3 and the winding module 4 from the two opposite sides of the planar transformer 1, the middle leg 24 is penetrated through the first opening 31 and the second opening 42.

In an embodiment, the region of the plastic molding layer 41 corresponding to the printed circuit board 3 further includes a receiving recess 43. The receiving recess 43 is concavely formed in a surface of the plastic molding layer 41. The shape and size of the receiving recess 43 match the shape and size of the printed circuit board 3. The receiving recess 43 provides a positioning function. That is, the printed circuit board 3 is disposed and limited in the receiving recess 43 of the plastic molding layer 41.

In an embodiment, the plastic molding layer 41 includes a first pin base 44. The first pin base 44 is located at a first side of the plastic molding layer 41. The first pin base 44 has a first top surface and a first bottom surface. The first top surface and the first bottom surface of the first pin base 44 are substantially in parallel with the printed circuit board 3. The planar transformer 1 further includes at least one first pin 5. When the plastic molding layer 41 is formed on the second winding 40 through the plastic injection molding process, the at least first pin 5 is installed on the first pin base 44 of the plastic molding layer 41. The first pin 5 is substantially perpendicular to the first top surface and the first bottom surface of the first pin base 44. In addition, a portion of the first pin 5 is covered by the plastic molding layer 41, and another portion of the first pin 5 is exposed outside the first top surface and the first bottom surface of the first pin base 44 and perpendicularly protruded from the first pin base 44. The portion of the first pin 5 exposed outside the first pin base 44 is electrically connected with the traces or conductors of the printed circuit board 3 through a welding process. For example, the first pin 5 is electrically connected with the first winding 30 through the welding process. Moreover, the at least one first pin 5 can be mounted on a system board (not shown).

In an embodiment, the printed circuit board 3 includes at least one accommodation notch 32. The accommodation notch 32 is concavely formed in an edge of the printed circuit board 3 and located beside the first pin base 44. The at least one accommodation notch 32 is aligned with the corresponding first pin 5. At least a portion of each first pin 5 is accommodated within the corresponding accommodation notch 32. Consequently, the first pin 5 is electrically connected with the traces or the conductors of the printed circuit board 3 through the corresponding accommodation notch 32. In an embodiment, the accommodation notch 32 has a semicircular structure. It is noted that the structure of the accommodation notch 32 is not restricted.

In an embodiment, the plastic molding layer 41 includes a second pin base 45. The second pin base 45 is located at a second side of the plastic molding layer 41. The first side and the second side of the plastic molding layer 41 are opposed to each other. The second pin base 45 has a second top surface and a second bottom surface. The second top surface and the second bottom surface of the second pin base 45 are substantially in parallel with the printed circuit board 3. The winding module 4 further includes at least one second pin 46. As shown in FIG. 3, the winding module 4 includes two second pins 46. At least a portion of the second pin 46 is installed on the second pin base 45. A first terminal of each second pin 46 is connected with a corresponding terminal part of the second winding 40 and disposed within the second pin base 45. A second terminal of each second pin 46 is exposed outside the second top surface or the second bottom surface of the second pin base 45 and perpendicularly protruded from the second pin base 45. The second pins 46 can be mounted on the system board. In an embodiment, the two second pins 46 are integrally formed with the two opposite terminal parts of the second winding 40. In other words, the two second pins 46 are extended from the two opposite terminal parts of the second winding 40. Moreover, each second pin 46 is bent at least one time from the corresponding terminal part of the second winding 40, and thus the angle between each second pin 46 and the corresponding terminal part of the second winding 40 is 90 degrees. Consequently, the second terminal of each second pin 46 can be exposed outside the second top surface or the second bottom surface of the second pin base 45.

As mentioned above, the second winding is formed by winding a conductive sheet. Optionally, the conductive sheet includes a flat surface 400 and a concave part 401. The concave part 401 is concavely formed in the flat surface 400. Due to the arrangement of the concave part 401, the skin effect is reduced, and the conversion efficiency of the planar transformer 1 is increased. Similarly, in case that the second pins 46 are integrally formed with the corresponding terminal parts of the second winding 40, the second pins 46 also have the concave parts.

As shown in FIG. 1, the planar transformer 1 further includes a conductive glue 6. The conductive glue 6 is disposed between the magnetic core assembly 2 and the printed circuit board 3. The magnetic core assembly 2 and the printed circuit board 3 are electrically connected with each other through the conductive glue 6. In an embodiment, the conductive glue 6 is disposed between a middle region of the magnetic core assembly 2 and a ground terminal of the printed circuit board 3.

Please refer to FIG. 4 again. In addition to the first winding 30, the printed circuit board 3 includes at least one auxiliary winding 33 and at least one shielding structure 34. Each auxiliary winding 33 and each shielding structure 34 can be disposed in one or a plurality of layers of the printed circuit board 3. That is, the locations of the auxiliary winding 33 and the shielding structure 34 are not restricted to those as shown in FIG. 4. The auxiliary winding 33 and the first winding 30 are collaboratively formed as the primary winding or the secondary winding of the planar transformer 1. In addition, the auxiliary winding 33 is used as a control signal line. The diameter of the auxiliary winding 33 is smaller than or equal to the diameter of the first winding 30. The shielding structure 34 is a metal conductor structure that is used to suppress electromagnetic interference (EMI). In an embodiment, at least one layer of the printed circuit board 3 includes the first winding 30. Moreover, each layer of the printed circuit board 3 includes at least one of the first winding 30, the auxiliary winding 33 and the shielding structure 34.

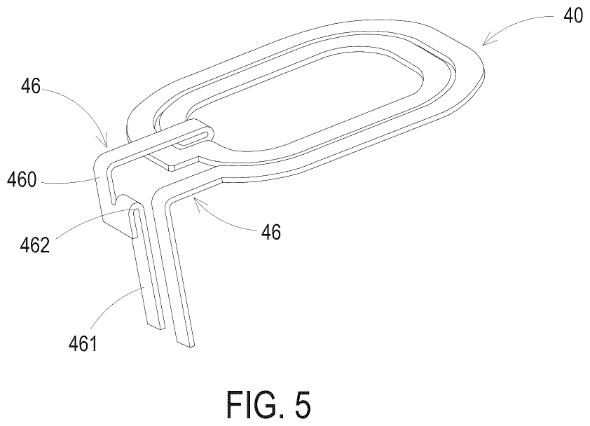

FIG. 5 is a schematic perspective view illustrating a variant example of the second winding of the planar transformer according to the first embodiment of the present disclosure. As shown in FIG. 5, at least one second pin 46 includes a first bent segment 460 and a second bent segment 461. The first bent segment 460 is connected between the corresponding terminal part of the second winding 40 and the second bent segment 461. Moreover, at least a portion of the first bent segment 460 is disposed within the second pin base 45. The first bent segment 460 is bent one time from the terminal part of the second winding 40. At least a portion of the second bent segment 461 is exposed outside the second top surface or the second bottom surface of the second pin base 45 and perpendicularly protruded from the second pin base 45. The second bent segment 461 is bent one time from the terminal part of the first bent segment 460. Consequently, the bent region of the second bent segment 461 has a U-shaped structure 462. The formation of the U-shaped structure 462 can increase the overall length of the second winding 40.

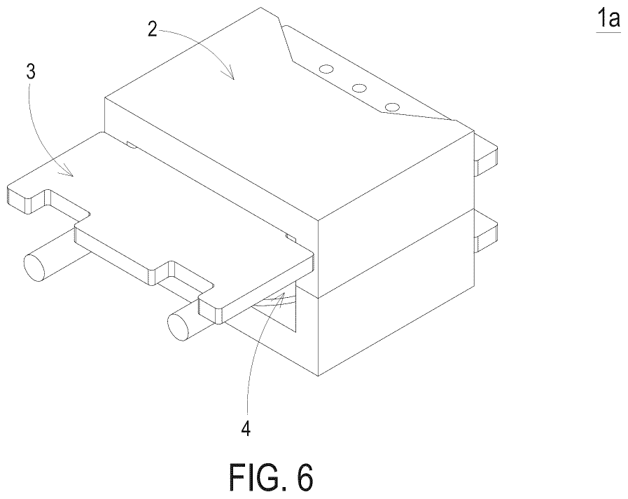

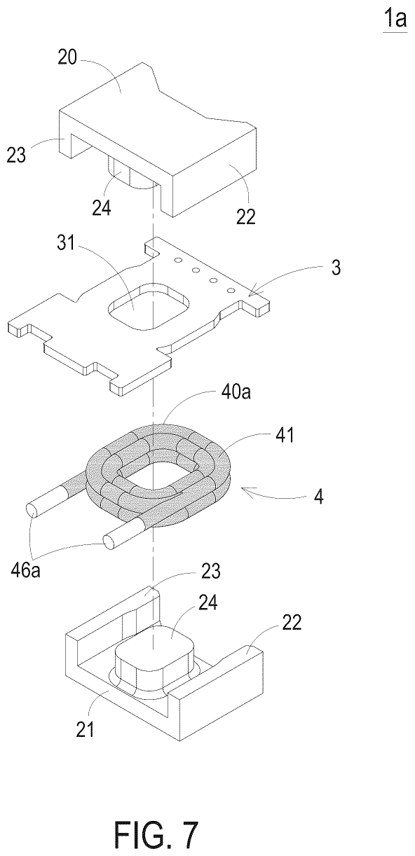

Please refer to FIGS. 6 and 7. FIG. 6 is a schematic perspective view illustrating an assembled structure of a planar transformer according to a second embodiment of the present disclosure. FIG. 7 is a schematic exploded view illustrating the planar transformer as shown in FIG. 6. The structure of the planar transformer 1a of this embodiment is similar to that the planar transformer 1 as shown in FIG. 1. Component parts and elements corresponding to those of the first embodiment are designated by identical numeral references, and detailed descriptions thereof are omitted. In the embodiment of FIG. 1, the second winding 40 of the winding module 4 is implemented with a conductive sheet. In comparison with the first embodiment, the second winding 40a of the winding module 4 in this embodiment is a winding coil. Similarly, the plastic molding layer 41 is formed on the second winding 40a through a plastic injection molding process, wherein at least a portion of the second winding 40a is covered by the plastic molding layer 41. In addition, the first terminal of each second pin 46a of the winding module 4 is connected with the corresponding terminal part of the second winding 40a. Preferably, each second pin 46a of the winding module 4 is integrally formed with the corresponding terminal part of the second winding 40a.

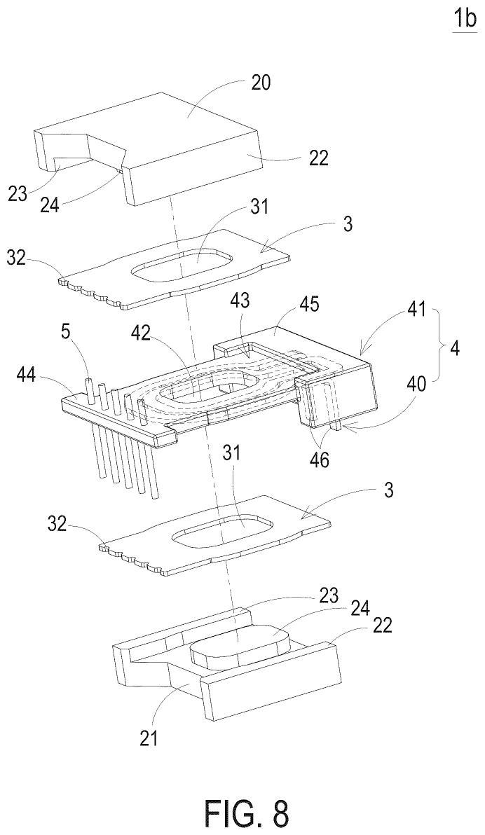

FIG. 8 is a schematic exploded view illustrating a planar transformer according to a third embodiment of the present disclosure. The structure of the planar transformer 1b of this embodiment is similar to that of the planar transformer 1 as shown in FIG. 1. Component parts and elements corresponding to those of the first embodiment are designated by identical numeral references, and detailed descriptions thereof are omitted. In comparison with the planar transformer 1 of FIG. 1, the planar transformer 1b of this embodiment includes two printed circuit boards 3. In this embodiment, one of the two printed circuit boards 3 is disposed between the first magnetic core 20 and the winding module 4, and the other of the two printed circuit boards 3 is disposed between the second magnetic core 21 and the winding module 4.

It is noted that numerous modifications and alterations may be made while retaining the teachings of the disclosure. For example, the number of the at least one printed circuit board and the number of the at least one winding module of the planar transformer may be varied according to the practical requirements. For example, in another embodiment, the planar transformer includes two winding modules and one printed circuit board.

From the above descriptions, the present disclosure provides a planar transformer. The planar transformer includes at least one printed circuit board and at least one winding module. The at least one printed circuit board and the at least one winding module are individual components. The printed circuit board includes a first winding. The winding module includes a second winding. Due to the special structural design, the production cycle of the planar transformer is shortened, the fault tolerance rate is increased, the fabricating cost is reduced, and the adjusting flexibility is enhanced.

While the disclosure has been described in terms of what is presently considered to be the most practical and preferred embodiments, it is to be understood that the disclosure needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A planar transformer, comprising:
a magnetic core assembly comprising a first magnetic core and a second magnetic core;
at least one printed circuit board disposed between the first magnetic core and the second magnetic core, wherein the printed circuit board comprises a first winding; and
at least one winding module disposed between the first magnetic core and the second magnetic core, wherein the winding module comprises a second winding and a plastic molding layer, and at least a portion of the second winding is covered by the plastic molding layer,
wherein the at least one printed circuit board and the at least one winding module are individual components.

2. The planar transformer according to claim 1, wherein one of the first winding and the second winding is a primary winding of the planar transformer, and the other of the first winding and the second winding is a secondary winding of the planar transformer.

3. The planar transformer according to claim 1, wherein a thickness of the second winding is in a range between 0.01 mm and 1.5 mm, and a thickness of the plastic molding layer is in a range between 0.4 mm and 0.8 mm.

4. The planar transformer according to claim 1, wherein the plastic molding layer comprises a receiving recess corresponding to the printed circuit board, wherein the receiving recess is concavely formed in a surface of the plastic molding layer, and the printed circuit board is disposed and limited in the receiving recess of the plastic molding layer.

5. The planar transformer according to claim 1, wherein the plastic molding layer comprises a first pin base, and the first pin base is located at a first side of the plastic molding layer, wherein the first pin base has a first top surface and a first bottom surface, and the first top surface and the first bottom surface are in parallel with the printed circuit board, wherein the planar transformer further comprises at least one first pin, wherein the at least one first pin is installed on the first pin base, a portion of each first pin is covered by the plastic molding layer, another portion of each first pin is exposed outside the first top surface and the first bottom surface of the first pin base and perpendicularly protruded from the first pin base, and the at least one first pin is electrically connected with the first winding.

6. The planar transformer according to claim 5, wherein the printed circuit board comprises at least one accommodation notch, wherein the at least one accommodation notch is concavely formed in an edge of the printed circuit board, and a portion of each first pin is accommodated within the corresponding accommodation notch.

7. The planar transformer according to claim 5, wherein the plastic molding layer comprises a second pin base, and the second pin base is located at a second side of the plastic molding layer, wherein the first side and the second side of the plastic molding layer are opposed to each other, the second pin base has a second top surface and a second bottom surface, and the second top surface and the second bottom surface of the second pin base are in parallel with the printed circuit board, wherein the winding module further comprises at least one second pin, wherein the at least one second pin is installed on the second pin base, a portion of each second pin is covered by the plastic molding layer, another portion of each second pin is exposed outside the second top surface or the second bottom surface of the second pin base and perpendicularly protruded from the second pin base, and the at least one second pin is electrically connected with the second winding.

8. The planar transformer according to claim 7, wherein the second pin comprises a first bent segment and a second bent segment, wherein the first bent segment is connected between the second winding and the second bent segment, a portion of the first bent segment is disposed within the second pin base, and the first bent segment is bent one time from a terminal part of the second winding, wherein a portion of the second bent segment is exposed outside the second top surface or the second bottom surface of the second pin base and perpendicularly protruded from the second pin base, and the second bent segment is bent one time from a terminal part of the first bent segment, wherein a bent region of the second bent segment has a U-shaped structure.

9. The planar transformer according to claim 1, wherein the second winding is formed by performing a stamping process on a conductive sheet.

10. The planar transformer according to claim 9, wherein the second winding comprises a flat surface and a concave part, wherein the concave part is concavely formed in the flat surface of the second winding.

11. The planar transformer according to claim 1, wherein the planar transformer further comprises a conductive glue, wherein the conductive glue is disposed between the magnetic core assembly and a ground terminal of the printed circuit board.

12. The planar transformer according to claim 1, wherein the printed circuit board comprises at least one layers, and the printed circuit board comprises at least one auxiliary winding and at least one shielding structure, wherein the at least one auxiliary winding and the first winding are collaboratively formed as a primary winding or a secondary winding of the planar transformer, the auxiliary winding is a control signal line, and the shielding structure is a metal conductor structure, wherein at least one layer of the printed circuit board comprises the first winding, and each layer of the printed circuit board comprises at least one of the first winding, the auxiliary winding and the shielding structure.

13. The planar transformer according to claim 1, wherein the second winding is a winding coil.
